(19) United States
(12) Patent Application Publication
(10) Pub. No.: US 2006/0084276 A1
(43) Pub. Date: Apr. 20, 2006

(54) Methods for surface treatment and structure formed therefrom

(76) Inventors: Janet Yu, Hsin Chu (TW); Fu-Kai Yang, Hsinchu City (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 10/965,575

(22) Filed: Oct. 14, 2004

(51) Int. Cl. H01L 21/42

(52) U.S. Cl. 438/712; 438/732; 438/795

(57) ABSTRACT

A method for patterning a resist protection oxide (RPO) layer and a structure formed therefrom are disclosed. The method forms a RPO layer over a substrate. A patterned photoresist layer is formed over the RPO layer. A process is performed for bombarding a surface of the RPO layer by using ions which substantially do not chemically react with the RPO layer. A portion of the RPO layer is removed. The patterned photoresist layer is then removed. Accordingly, a RPO structure formed by the method described above is also disclosed.

### BACKGROUND OF THE INVENTION

1. Field of the Invention

The present invention relates to the fabrication of integrated circuit devices on semiconductor substrates and, more particularly relates to methods for surface treatment and a structure formed therefrom.

2. Description of the Related Art

The Complementary Metal Oxide Semiconductor (CMOS) technology has been recognized as the leading technology for use in digital electronics in general and for use in many computer products in particular. The miniaturization of CMOS technology according to a scaling rule is used in a semiconductor device to achieve large-scale integration and high-speed operation. The advance CMOS technology has been applied to fabrication of static random access memory (SRAM).

In fabrication of SRAM, resistances of portions of polysilicon gates and active areas should be maintained in order to meet the requirement of integrated circuits. The resist protection oxide (RPO) process has been disclosed for achieving the purpose. By forming a patterned RPO layer covering the gates or the active areas that should not contact with a subsequent silicide metal layer, the inherent resistance of the gates and the active areas can be maintained. The desired performance of the integrated circuits fabricated by this method, therefore, is achieved.

Accordingly, a descum process has been widely used to discharge surface charges and treat the surface of the substrate. FIG. 1 is a flowchart showing a prior art method for forming a RPO structure. In the step S100, a RPO layer is formed over a substrate having polysilicon gates and active areas by chemical vapor deposition (CVD). In the step S102, a photolithographic process is performed for forming a patterned photoresist layer covering the RPO layer which is going to be defined. Then a descum step S104 is performed for removing charges and treating the surface of the RPO layer by using oxygen plasma in an ion coupled plasma (ICP) chamber. A fluorine acid solution is used in the step S106 so as to remove a portion of the RPO layer which is not covered by the patterned photoresist layer. In the step S108, the patterned photoresist is removed. The prior art process, however, leaves pits on the polysilicon gates and the active areas. Due to these pits, the test of gate oxide integrity fails. Accordingly, the prior art method does not provide a desired RPO structure for fabrication of integrated circuits.

U.S. Patent Application Publication 2002/0012889 A1 discloses a surface treatment for enhancing hydrophobicity of photographic support and photothermographic material by use thereof. The prior art method subjecting at least one side of the surface to a gas-discharge plasma treatment in a gas phase atmosphere comprising (a) an inert gas comprising argon or helium and (b) a reactive gas comprising a hydrocarbon gas or fluorinated hydrocarbon gas. There is also disclosed a photothermographic material by the use of the support having been subjected to the surface treatment.

U.S. Patent Application Publication 2001/0001707 A1 discloses a treatment for silicon oxy-nitride. The method for treating a surface, including a silicon oxynitride surface covered by a photo resist layer, is described in which the photo resist layer is first removed by an oxygen plasma treatment process, followed by an argon plasma treatment process to overetch the SiON layer.

### SUMMARY OF THE INVENTION

A surface treatment method for a dielectric layer with a patterned photoresist layer thereon is performed by bombarding a surface of the dielectric layer by using ions so as to discharge charges on the dielectric layer.

A descum method comprises providing a substrate with a dielectric layer thereon, and a patterned photoresist layer on the dielectric layer; and bombarding a surface of the dielectric layer by using ions generated by a plasma power no more than about 800 Watts.

A method for patterning a resist protection oxide (RPO) layer is disclosed. The method forms a RPO layer over a substrate. A patterned photoresist layer is formed over the RPO layer. A process is performed for bombarding a surface of the RPO layer by using ions which substantially do not chemically react with the RPO layer. A portion of the RPO layer is removed. The method also removes the patterned photoresist layer. Accordingly, a RPO structure formed by the method described above is also disclosed.

The above and other features of the present invention will be better understood from the following detailed description of the preferred embodiments of the invention that is provided in connection with the accompanying drawings.

### BRIEF DESCRIPTION OF THE DRAWINGS

FIG. 1 is a flowchart showing a prior art method for forming a RPO structure.

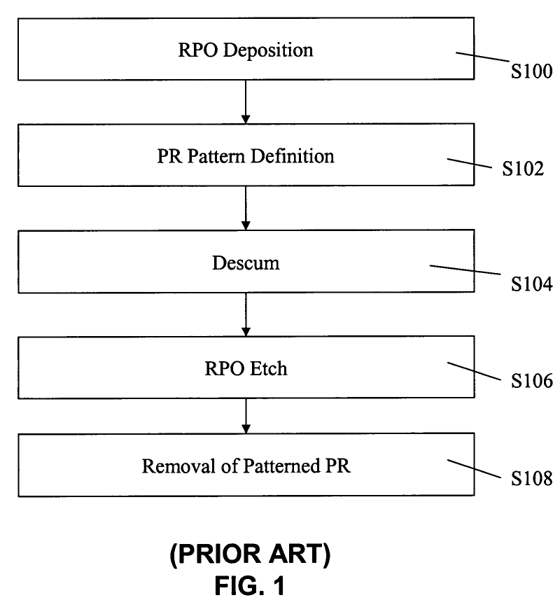

FIG. 2 is a flowchart showing an exemplary method for forming a resist protection oxide (RPO) structure.

### DESCRIPTION OF THE PREFERRED EMBODIMENTS

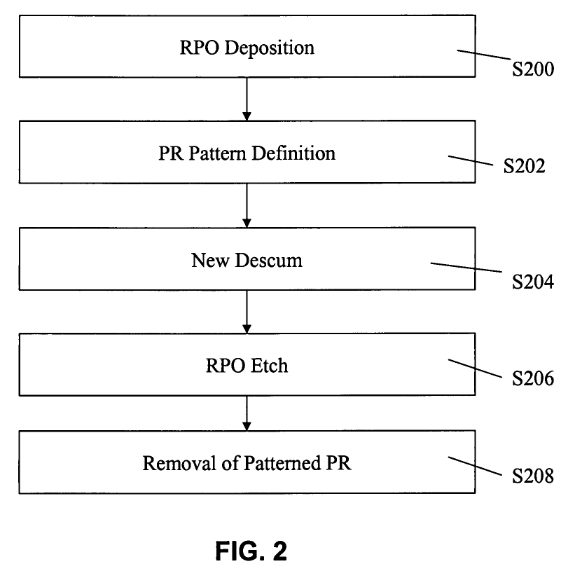

Referring to FIG. 2, the step S200 forms a RPO layer over a substrate. The structure can be, for example, a silicon substrate, a III-V compound substrate, or a glass substrate. The substrate may also comprise shallow trench isolation (STI) structures and gate structures formed thereon. The RPO layer is, therefore, formed over the STI structures and the gate structures. The RPO layer is a dielectric layer which can be, for example, an oxide layer, a nitride layer, an oxy-nitride layer or the like that can substantially serve the function similar thereto. The RPO layer can be formed by, for example, chemical vapor deposition (CVD). In this embodiment, the RPO layer is an oxide layer.

The step S202 defines a photoresist pattern. By coating a photoresist layer over the structure described in the step S200, a subsequent exposure step and a subsequent development step are performed so as to form the photoresist pattern over the RPO layer. The photoresist layer can be, for example, normal photoresist or deep UV photoresist.

The step S204 relates to using a new descum process to treat the surface of the RPO layer. In some embodiments, this method bombards the surface of the RPO layer by using ions so as to discharge charges on the RPO layer. In some embodiments, the ions substantially do not chemically react with the RPO layer. For example, the ions may be generated from an inert gas. In this embodiment the inert gas is argon. In other embodiments, the ions, such as fluorine ions, may chemically react with the RPO layer as long as the chemical reaction does not substantially damage the surface of the RPO layer. From the descriptions of this embodiment, one of ordinary skill in the art will understand that the selection of the reaction gas may affect the damage on the surface of the RPO layer and, therefore, know how to select the reaction gas.

In a preferred embodiment, the step S204 may be performed in a dipole ring magnet etcher or any other etcher that may generate an electrical field accelerating the ions so as to bombard the surface of the RPO layer. In some embodiments, the plasma power used in this step, which is no more than about 800 Watts, may create the bombardment effect similar to that of using a dipole ring magnet etcher. By applying the plasma power, the etch may generate a direct current (DC) bias from about 500 V to about 1,200 V. One of ordinary skill in the art, after viewing the descriptions of this embodiment, will understand that the dipole ring magnet etcher or the like may generate the same etch bombardment effect. It is not necessary that the step S204 be performed in the dipole ring magnet etcher as long as the other etcher can create the similar bombardment effect.

In some embodiments, the pressure used in the step S204 is no more than 50 mTorr. In a preferred embodiment, the pressure is about 20 mTorr. In some embodiments, the flow rate of the inert gas is from about 200 sccm to about 1000 sccm. In a preferred embodiment, the flow rate of argon is about 200 sccm. In some embodiments, the process time of the step S204 is from about 10 seconds to about 60 seconds. In a preferred embodiment, the process time is about 10 seconds. The conditions of the step S204 are modifiable and not limited thereto. One of ordinary skill in the art, after viewing the descriptions of this embodiment, will understand the importance of fine tuning these conditions so as to generate a desired treatment process and know how to fine tune these conditions.

Accordingly, a preferred embodiment comprises a process for treating the surface of the dielectric layer in a dual ring magnetic etcher with argon having the pressure about 50 mTorr, the plasma power about 500 W, the flow rate about 200 sccm and the process time of about 10 seconds.

In step S206, a RPO etch process is performed so as to remove a portion of the RPO layer which is not covered by the patterned photoresist layer. The RPO etch process can be, for example, a dry etch process, a wet etch process or a combination thereof. In this embodiment, the RPO etch process is a wet etch process which uses fluorine acid to remove the exposed RPO layer.

In step S208, a process for removing the patterned photoresist layer is performed so as to form the RPO structure. The step S208 can remove the patterned photoresist layer, for example, by using an oxygen plasma dry etch process or a wet etch process with chemicals that can remove the patterned photoresist layer.

Although the present invention has been described in terms of exemplary embodiment, it is not limited thereto. Rather, the appended claims should be construed broadly to include other variants and embodiments of the invention which may be made by those skilled in the field of this art without departing from the scope and range of equivalents of the invention.

What is claimed is:

1. A surface treatment method for a dielectric layer with a patterned photoresist layer thereon, which comprises bombarding a surface of the dielectric layer by using ions so as to discharge charges on the dielectric layer.

2. The surface treatment method of claim 1, which is performed in a dipole ring magnet etcher.

3. The surface treatment method of claim 1, wherein a plasma power of the surface treatment method is no more than about 800 Watts.

4. The surface treatment method of claim 3, wherein a direct current (DC) bias generated by the plasma power is from about 500 V to about 1,200 V.

5. The surface treatment method of claim 1, wherein a pressure of the surface treatment method is no more than about 50 mTorr.

6. The surface treatment method of claim 1, wherein the ions do not substantially chemically react with the dielectric layer.

7. The surface treatment method of claim 6, wherein the ions are created from an inert gas.

8. The surface treatment method of claim 7, wherein the inert gas is argon.

9. The surface treatment method of claim 1, wherein a gas flow rate of the surface treatment method is from about 200 sccm to about 1,000 sccm, and a process time of the surface treatment method is from about 10 seconds to about 60 seconds.

10. A descum method, comprising:
providing a substrate with a dielectric layer thereon, and a patterned photoresist layer on the dielectric layer; and
bombarding a surface of the dielectric layer by using ions generated by a plasma power no more than about 800 Watts.

11. The descum method of claim 10, wherein the dielectric layer comprises a resist protection oxide (RPO) layer.

12. The descum method of claim 10, wherein the step of bombarding is performed in a dipole ring magnet etcher.

13. The descum method of claim 10, wherein a direct current (DC) bias generated by the plasma power is from about 500 V to about 1,200 V.

14. The descum method of claim 10, wherein a pressure of the surface treatment method is no more than about 50 mTorr.

15. The descum method of claim 10, wherein the ions do not substantially chemically react with the dielectric layer.

16. The descum method of claim 15, wherein the ions are created from an inert gas.

17. The descum method of claim 16, wherein the inert gas is argon.

18. The descum method of claim 10, wherein a gas flow rate of the surface treatment method is from about 200 sccm to about 1,000 sccm, and a process time of the surface treatment method is from about 10 seconds to about 60 seconds.

19. A method for patterning a resist protection oxide (RPO) layer, comprising:
forming a RPO layer over a substrate;
forming a patterned photoresist layer over the RPO layer;
bombarding a surface of the RPO layer by using ions which substantially do not chemically react with the RPO layer;
removing a portion of the RPO layer; and
removing the patterned photoresist layer.

20. The method for patterning a RPO layer of claim 19, wherein the step of bombarding is performed in a dipole ring magnet etcher.

21. The method for patterning a RPO layer of claim 19, wherein the ions are generated from an inert gas by using a plasma power no more than about 800 Watts which generates a direct current (DC) bias from about 500 V to about 1,200 V.

22. The method for patterning a RPO layer of claim 21, wherein the inert gas is argon.

23. The method for patterning a RPO layer of claim 19, wherein a pressure of the surface treatment method is no more than about 50 mTorr.

24. The method for patterning a RPO layer of claim 19, wherein a gas flow rate of the surface treatment method is from about 200 sccm to about 1,000 sccm, and a process time of the surface treatment method is from about 10 seconds to about 60 seconds.

25. A resist protection oxide (RPO) structure formed by the method of claim 19.
